(19) United States
(12) Patent Application Publication
(10) Pub. No.: US 2026/0023140 A1
(43) Pub. Date: Jan. 22, 2026

(54) Magnetic Imaging Systems and Methods

(71) Applicant: Yale University, New Haven, CT (US)

(72) Inventors: Robert Todd Constable, Madison, CT (US); Gigi Galiana, Guilford, CT (US)

(21) Appl. No.: 19/272,802

(22) Filed: Jul. 17, 2025

Related U.S. Application Data
(60) Provisional application No. 63/672,885, filed on Jul. 18, 2024.

(51) Int. Cl. G01R 33/34; G01R 33/44

(52) U.S. Cl. CPC G01R 33/34007; G01R 33/445

(57) ABSTRACT

Described herein are compact MRI systems having (i) an open, field-cycling magnet configured to produce and cycle between a first and second non-uniform B₀ different from the first non-uniform B₀, and (ii) a second component configured to produce a nonlinear spatial encoding gradient. Importantly, the open, field-cycling magnet and the spatial encoding gradients are customized to a specific imaging application. In particular, the second component contains one or several nonlinear DC gradient coils for spatial encoding. It also contains one or several a radiofrequency coils geometrically configured to have a non-planar configuration. Lastly, both the RF coils and DC encoding gradients are tailored specifically to the first non-uniform B₀ magnetic field, the second non-uniform B₀ magnetic field, or both. Artificial intelligence models trained to read imaging data can be incorporated as a component of the MRI systems. Also described are methods of using the disclosed MRI systems.

### CROSS REFERENCE TO RELATED APPLICATIONS

This application claims priority to and benefit of U.S. Provisional Application No. 63/672,885 filed on Jul. 18, 2024, the disclosure of which is hereby incorporated herein by reference in its entirety.

### FIELD OF THE INVENTION

The invention is in the field of diagnostic imaging, particularly magnetic resonance imaging (MRI) systems and methods, and more preferably MRI systems and methods that use a combination of (i) a small, open, field-cycling magnet to cycle between nonhomogeneous B₀ fields, (ii) radiofrequency coils having a non-planar configuration for non-linear spatial encoding, and (iii) direct current (DC) gradients for non-linear spatial encoding.

### BACKGROUND OF THE INVENTION

In conventional magnetic resonance imaging (MRI) systems, a spatially uniform main magnetic field is needed in the imaging region because large field gradients dephase the signal before it can be acquired. This requirement of conventional MRI severely limits the design opportunities of the main magnet, and the dependence on linear gradient fields for spatial encoding also constrains the designs. In both cases, this typically leads to an MRI system with large, cylindrically shaped magnets surrounding an examination table where the patient is positioned. This closed design of the magnet is not suitable for imaging claustrophobic patients and does not allow easy medical interventions or imaging of obese individuals. Conventional MRI systems are also very expensive. The high manufacture and operational cost associated with building superconducting magnets with uniform magnet fields prevents widespread availability of MR imaging, especially for MR as an initial screening tool. Another challenge that conventional MRI systems encounter involves time, resource intensive exams, and need for experts to examine the results to arrive at a diagnosis. This requirement for human experts means that diagnosis highly depends on the experience of the analysis and often can be subjective. Accordingly, an unmet need exists to provide MRI systems and techniques that overcome the limitations of conventional MRI.

Therefore, it is an object of the invention to provide MRI systems that alleviate one or more of the limitations described above.

It is also an object of the invention to provide MRI systems with primary magnets and/or radiofrequency coils that are customizable and/or customized to a specific anatomy being imaged.

### SUMMARY OF THE INVENTION

Described herein are compact MRI systems having a first component containing an open, field-cycling magnet configured to produce and cycle between a first non-uniform B₀ and a second non-uniform B₀, that is different from the first non-uniform B₀ (B₀ denotes a magnetic field generated by a primary magnet in the MRI system). The compact MRI systems have a footprint of less than about 1 m². The MRI systems further contain a second component containing one or a plurality of second components operably linked to the first component and configured to produce one or a plurality of nonlinear spatial encoding gradients that span a three-dimensional volume space. Importantly, the open, field-cycling magnet and/or the spatial encoding gradients are customizable and/or customized to a specific imaging application. The customization can be hardware specific (e.g., geometry) and/or software specific (e.g., algorithms for image reconstruction). In some forms, the one or the plurality of second components contain one or more radiofrequency (RF) coils with non-planar configuration, a non-horizontal configuration, or both, geometrically configured to receive signal from spins precessing perpendicularly to the non-uniform B₀ magnetic field for the customized B₀ geometry described above. In some forms, the one or the plurality of second components contain DC gradients for non-linear spatial encoding, provided by gradient coils (e.g., local gradient coils such as x-, y-, and/or z-local gradient coils). Lastly, the non-linear spatial encoding gradients are tailored specifically to the first non-uniform B₀ magnetic field, the second non-uniform B₀ magnetic field, or both. Some advantages of these design features are that the open, field-cycling magnet, the radiofrequency coils, and/or the gradient coils are customized to provide improved sensitivity at greater tissue depths in an anatomy being imaged and anatomy-specific spatial encoding gradients, such that the MRI system performs at a high signal-to-noise ratio for a given anatomical structure. In addition, nonuniform and nonlinear magnetic fields generally have fewer design constraints and are cheaper to build.

The ability to perform MRI using a nonuniform main magnetic field allows the MRI system to have an open magnet design, which has many practical advantages. The system is potentially inexpensive because of the relaxed construction requirements in building a magnet that does not need to generate a uniform main magnetic field or linear encoding gradients; the system can be more quiet than conventional MRI systems because in some forms, no gradient coils are required; and the open magnet design allows scanning of claustrophobic subjects. The open design also allows a compact MRI system having wider range of shapes and sizes (e.g., having a footprint of less than about 1 m²). For example, it allows a compact MRI system to be built into an examination table or wall. A vertical design could be dedicated to weighted-spine imaging. Other small devices could be designed for specific applications in imaging the brain, breast, liver, spine, prostate, heart, or gynecologic parts. In some forms, these devices could be designed for specific applications that do not involve breast imaging. This allows physicians to perform preliminary scanning in the doctor's office or in the field, similar to how ultrasound imaging is used today, making it widely accessible in doctor's offices. Portable MRI systems are also envisioned. The technique also can be applied to MR based material analysis, MR spectroscopy, and solid material NMR. In some forms, as noted above, direct current (DC) gradients for non-linear spatial encoding can be generated using gradient coils (e.g., local gradient coils such as x-, y-, and/or z-local gradient coils). Lastly, in some forms the systems and methods incorporate one or more RF coils (non-planar, non-horizontal, or both) having a configuration that acquires signal from a targeted anatomy in the context of alternative main magnet geometry. The RF geometry encompasses or achieves proximity to a targeted anatomy, and the orientation of the RF is designed to capture the spatially varying orientation of precession arising from the non-uniform B₀ field.

These advantages are made possible by a combination of innovative techniques that liberate MRI from the requirement of a uniform main magnetic field. In contrast with conventional MRI, the MRI systems described herein can provide high quality images using a nonuniform main magnetic field. This is facilitated by using an electromagnet to generate and cycle a nonuniform main magnetic field between a high field for spin polarization and a lower field for slice selection and MR signal readout; using multicoil arrays for spin excitation and receiving MR signals; and using non-linear DC gradients optionally in combination with RF spin-manipulation, for spatial encoding. The provisional of high quality images can also be facilitated by using an electromagnet to generate and cycle a nonuniform main magnetic field between a high field for spin polarization and a lower field for slice selection and MR signal readout; using multicoil arrays for spin excitation, receiving MR signals, and non-linear spatial encoding, where the multicoil arrays, preferably in a non-planar and/or non-horizontal configuration, produce a spatial encoding gradient that spans a three-dimensional volume space. Preferably, the image is reconstructed using reconstruction techniques and parallel imaging. To address the need for expert, and potential subject assessments of imaging data, artificial intelligence models (machine learning and/or deep learning algorithms) can be trained to assist in reading the imaging data, tested, and incorporated as a component of the MRI systems.

Also described are methods of using the disclosed MRI systems. An electromagnet is used to generate a spatially nonuniform magnetic field within an imaging region. By controlling current through the electromagnet, the nonuniform magnetic field is repeatedly cycled between a first strength for polarizing spins and a second strength, lower than the first strength, for spatial encoding and readout. Using one or more RF coils with appropriate configuration, excitation pulses are generated at a frequency that selects a non-planar isofield slice for imaging. The RF coils are also used to generate refocusing pulses for imaging and optionally to generate spatial encoding pulses. An alternative to using the RF coils to generate spatial encoding pulses, is the use of non-linear DC gradients obtained from gradient coils (e.g., local gradient coils such as x-, y-, and/or z-local gradient coils). Magnetic resonance signals originating from the selected non-planar isofield slice of the nonuniform magnetic field in the imaging region are detected using the RF coils in receive mode. The receive mode can be parallel (e.g., multi-channel) or single channel. MRI images are reconstructed from the received magnetic resonance signals with spatial encoding provided by either RF spatial encoding, DC nonlinear gradient encoding, or their combination.

The nonuniform magnetic field can have a large spatial variation exceeding 5 ppm, 10 ppm, 20 ppm, 30 ppm, 40 ppm, 50 ppm, 60 ppm, 70 ppm, 80 ppm, 90 ppm, or 100 ppm within the imaging region, such as between 5 ppm and 500 ppm, preferably between 100 ppm and 500 ppm

The electromagnet may be an open-geometry electromagnet that extends around the imaging region by no more than 270 degrees.

The first strength for polarizing spins can be at least 0.2 T (e.g., from 0.2 T to 1.0 T) and the second strength for spatial encoding and readout can be at most 0.1 T (e.g., from 10 mT to 0.1 T). In some forms, the first strength can be at least 0.6 T (e.g., 0.6 T to 1.0 T) and the second strength for spatial encoding and readout can be at most 0.1 T (e.g., 24 mT to 0.1 T).

In some forms, the RF coils contain a phased array of coils. The spatial encoding is nonlinear spatial encoding. The spatial encoding can be generated via the Bloch-Siegert shift or other spatial encoding pulses. The refocusing pulses generated using RF coils may include 180-degree RF pulses inserted to refocus the effects of the residual static gradient fields.

In some forms, the RF coils may contain first and second subsets of coils with no common coils, and spatial encoding can be generated using the first subset of the RF coils, while selecting a non-planar isofield slice and detecting magnetic resonance signals using the RF coils in parallel receive mode uses the second subset of the RF coils.

In some forms, the RF coils may contain first, second, and third subsets of coils with no common coils, and the first subset is used to generate spatial encoding, the second subset is used to select a non-planar isofield slice, and the third subset is used in parallel receive mode to detect magnetic resonance signals.

In some forms, spatial encoding can be performed with gradient coils that alter the local static (DC) magnetic field. Spatial encoding can be achieved solely by these gradients, which are non-linear. Spatial encoding by DC gradients can also be complemented with either RF encoding (e.g., Bloch-Siegert), the spatial encoding associated with parallel receive mode RF, or both. These gradients can also be used for spatially selective excitation.

In some forms, reconstructing MRI images from received magnetic resonance signals (e.g., multichannel imaging or single channel imaging) uses algebraic reconstruction. Preferably, the image reconstruction does not use standard Fourier-based image reconstruction because it cannot accommodate the nonlinear spatial encoding fields that are used for spatial localization.

### BRIEF DESCRIPTION OF THE DRAWINGS

FIGS. 1A-1E: a) The design of a two-element field-cycling electro-magnet. Winding for a single coil element (a), produces a nonuniform polarizing B0 field ranging from 0.6 T closest to the coil to 0.2 T at approximately 10 cm depth (measured vertically from the plane). B0-field direction is primarily L/R. Current is adjusted to yield high B0 field for polarizing the spins (maximizing signal), and a low field (24 mT, 1 MHz) during readout (minimizing non-uniform B0 effects). Such a magnet design can be used for spine MRI with the patient in the vertical position as the field lines follow the contour of the back and the maximum signal is obtained in the spine. The insert plot shows long T2-decay from 800 echoes following excitation. Most conventional pulse sequences are available as are additional contrast mechanisms through field-cycling. Signal intensity is determined by the polarizing field.

FIG. 2: B0 polarization reversal for T1 nulling. The rampable B0 can also be used to generate contrast. After reversal the field is on for time t-until either fat or water goes through zero, at which point the B0 is cycled to low field for imaging. Middle panel shows the recovery curve for water as a function of polarization reversal time τ−. Right panel shows experimental nulling of oil or water dependent upon τ−. With τ−=2.5 ms the oil is nulled while the water signal remains high (top row panel 3), whereas the opposite is true with τ−=800 ms, wherein the oil signal is high, and the water is nulled.

FIG. 3: Diffusion weighting with B0 magnet. Because of the nonuniformity of the B0 magnet, it can also be used to generate diffusion contrast. Strong diffusion encoding applied after the polarization period can be used to generate diffusion contrast. Very high b-values can be obtained with the intrinsic B0 field.

FIGS. 4A-4C: Field cycling with the NuBo system shows the command signal used to drive the electromagnet (blue lines) and the current through the magnet (red). The boxes in panel (a) and expanded in panels (b) and (c) and highlight the responses (and stabilization time (red) following the inputs (blue) for both rising amplitude (b) and falling amplitude (c). The stepped trajectory shown in (a) illustrates how slices can be selected as the 1 MHz isofrequency band is scanned through the object to be imaged. The settling time for the increasing field is of the order of 0.8 ms, and for the falling field it is of the order of 1.1 ms. After the field is lowered to 1 MHz in the plane of interest, the image encoding pulse sequence is applied to collect an image of that slice.

FIG. 5: Block diagram of the work distribution of the system. The controller can interface with the computer as well as each of the peripheral boards. The number of Tx/Rx boards is configurable.

FIGS. 6A and 6B. A pyramid phantom (a) composed of hollow pyramids and filled with doped water. The pyramids allow calibration of slice profiles, and image sharpness throughout the FOV. (b) A contrast detail phantom to measure contrast and resolution.

### DETAILED DESCRIPTION OF THE INVENTION

### I. Definitions

“Nonuniform,” as relates to a magnetic field, refers to a magnetic a field with more than about 100 ppm variation with respect to changes in spatial location in an imaging region. The field gradient of a nonuniform field could be linear or nonlinear. The orientation of the magnetic field vector can also vary considerably with respect to spatial location in an imaging region.

“Operably linked” refers to the connection of at least two components in an MRI system via technology including, but not limited to, integrated circuits, electrical cables, ethernet, internet, intranet, Bluetooth, near field communication, WiFi, or a combination thereof.

“Open,” as relates to the geometry of a magnet, refers to a magnet that does not completely surround an imaging region. As an example, the magnet surrounds the center of the region by at most 270 degrees.

### II. Magnetic Resonance Imaging Systems and Methods

Disclosed herein are MRI systems containing a first component containing an open, field-cycling magnet configured to produce a first non-uniform B₀ magnetic field and a second non-uniform B₀ magnetic field having a field strength different from that of the first non-uniform B₀ magnetic field, and one or a plurality of second components operably linked to the first component and configured to produce one or a plurality of nonlinear spatial encoding gradients. Nonlinear encoding, as relates to nonlinear spatial encoding encompasses both highly nonlinear as well as modest deviations from linearity. Preferably, the non-linear spatial encoding gradients in the MRI systems described herein span a three-dimensional volume space, whether generated using RF coils in a non-planar configuration, a non-horizontal configuration, or both; using gradient coils (e.g., local gradient coils such as x-, y-, and/or z-local gradient coils) using DC; or a combination thereof. Preferably, the MRI system is a compact MRI system (e.g., having a footprint less than about 1 m²) and suitable for operation in multi-purpose spaces or mixed-use rooms.

In some forms, the first non-uniform B₀ magnetic field has a field strength greater than that of the second non-uniform B₀ magnetic field and/or is configured to generate a slice-selective gradient. In some forms, one or plurality of second components contain: (i) one or more radiofrequency coils; (ii) one or more nonlinear DC gradient coils; or (iii) both (i) and (ii); capable of being configured to produce one or plurality of nonlinear spatial encoding gradients. In some forms, one or plurality of second components contain: (i) one or more radiofrequency coils; (ii) one or more nonlinear gradient coils; or (iii) both (i) and (ii); capable of being tailored specifically to the first non-uniform B₀ magnetic field, the second non-uniform B₀ magnetic field, or both. The alternative geometry generates a B0 magnetic field that can be non-uniform in both magnitude and orientation. RF must be tailored with sensitivity that complements the field direction at each location.

In some forms, one or a plurality of second components contain one or more radiofrequency coils, wherein the one or more radiofrequency coils have a non-planar configuration, a non-horizontal configuration, or both.

In some forms, one or a plurality of second components contain DC gradients for non-linear spatial encoding, preferably provided by gradient coils (e.g., local gradient coils such as x-, y-, and/or z-local gradient coils). In these forms, spatial encoding can be performed with gradient coils that alter the local static (DC) magnetic field. Spatial encoding can be achieved solely by these gradients, which are non-linear. Spatial encoding by DC gradients can also be complemented with either RF encoding (e.g., Bloch-Siegert), the spatial encoding associated with parallel receive mode RF, or both. These gradients can also be used for spatially selective excitation.

The disclosed MRI systems facilitate imaging using a main magnet with a highly nonuniform field operably linked to components configured to produce nonlinear spatial encoding gradients. This is made possible using techniques such as nonlinear MR imaging, field cycling MRI, RF based nonlinear spatial encoding, and imaging (e.g., multichannel imaging or single-channel imaging) with algebraic reconstruction.

Preferably, the MRI system includes a computer that is connected to one or several electromagnet power supplies, to an RF transmitter, and to an RF receiver. One power supply is connected to an open geometry electromagnet that generates a nonuniform magnetic field in an imaging region. The nonuniform magnetic field at least includes a nonuniform polarizing magnetic field. The electromagnet preferably contains one or more resistive coil elements. An open geometry in the present description means that the magnet does not completely surround the imaging region, e.g., it surrounds the center of the region by at most 270 degrees. The RF transmitter and RF receiver are connected to one or more arrays of RF coils positioned near the imaging region. In some forms, the open, field-cycling magnet; the spatial encoding gradients; or a combination thereof, are customizable and/or customized to a specific imaging application. In preferred forms, the open, field-cycling magnet and the spatial encoding gradients are customizable and/or customized to a specific imaging application.

More details of the disclosed MRI systems and methods are provided in the ensuing sections.

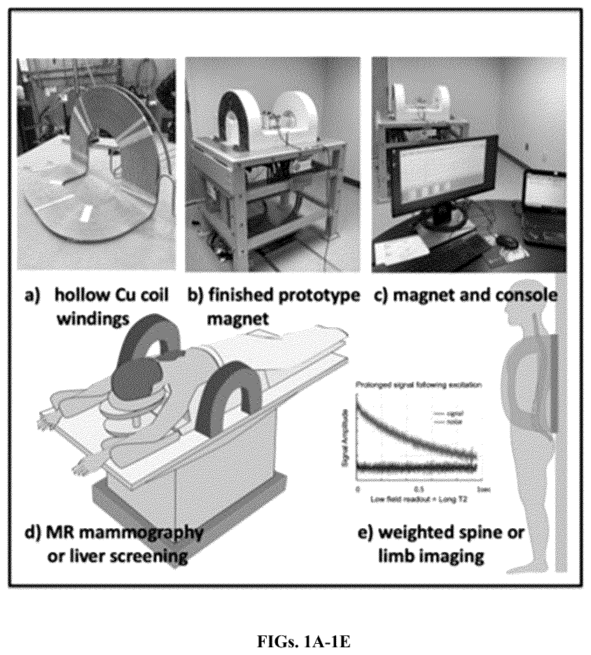

An important feature of the disclosed approach is the embracing of a nonuniform B₀-field in the magnet design. By eliminating the uniform B₀ constraint—which is the hallmark of most MRI systems—we free up the design possibilities and can tailor the magnet to the specific clinical application of interest. Currently most MRI systems use a cylindrical magnet, and only the RF coils are tailored to the specific application or anatomy. In the disclosed design the primary magnet, the RF and the spatial encoding gradients (DC spatial encoding gradient and/or spatial encoding gradients from the RF coils), are customized to the application. In conventional MR imaging magnets with significant B0 inhomogeneities cannot be used. Our approach allows high resolution imaging with a highly nonuniform B₀ magnet because we use a technique called field cycling. Field cycling allows us to polarize the spins at high field (thereby generating strong signal) and image at low field (thereby minimizing the effect of the inhomogeneous field) these innovations are described below. Reducing the B₀ field after spin polarization has two other advantages: 1) it reduces the RF power needed to manipulate spins (hence low-cost amplifiers can be used, and it also has the benefit of low specific absorption rate (SAR); and 2) it yields long T2s making very long echo trains feasible. We have designed and built such a system and proven it's feasibility for imaging. The original design, shown in FIGS. 1A-1D was aimed at generic body imaging with the goal of building an MRI system into a patient examination table. Spatial encoding in this initial prototype has been performed solely with RF (Mehring, et al., Phys Rev A Gen Phys 33, 3523-3526 (1986); Sacolick, et al., Official Journal of the Society of Magnetic Resonance in Medicine/Society of Magnetic Resonance in Medicine 63, 1315-1322 (2010)) and parallel receiver coils. We have shown that this nonuniform B0 (NuBo) system works as intended. However, features can be implemented to improve image quality for specific applications such as MRI of brain, breast, liver, spine, prostate, heart, or gynecologic parts. In some forms, features can be implemented to improve image quality for specific applications such as MRI of the brain, liver, spine, prostate, heart, or gynecologic parts. In some forms, these features can be implemented to improve image quality for specific applications that do not involve breast imaging. To achieve this anatomy-specific feature, RF coils can be included to increase the signal-to-noise ratio (SNR) (moving away from the planar RF arrays). DC spatial encoding gradients can also be used to increase spatial resolution. Spatial encoding can be wholly performed entirely by the aforementioned gradients, a combination of spatial encoding gradients and receive coils (e.g., parallel receive coils), a combination of spatial encoding gradients and RF encoding, or a combination of all three.

FIGS. 1A-1D illustrate a design we have built (the white, U-shaped magnet in the middle of the top row in the figure). The angular coil loops are curved up to enhance the field at depth (above the tabletop). Each coil element is composed of hollow copper wires (with deionized water for efficient cooling) with a maximum current of 275 Amps. Data disclosed herein show experimental proof that we can polarize spins at high field and readout signal at low field. It has also been observed that prepolarization increases SNR. In this operation, strong signals are obtained, with echoes recorded for up to 1 second after an excitation pulse. The low field readout allows short 180° RF pulses (for turbo-spin echo acquisitions) and yields very long T2s (we can collect 800 echoes in less than 1 second). In addition to enhancing this NuBo system by adding anatomy-specific gradients and RF, field-cycling and inhomogeneous B0 magnets in a geometry completely redesigned for anatomy-specific imaging can be developed. The anatomic structures can be, but not limited to, any one of those described above, such as brain, breast, liver, spine, prostate, heart, or gynecologic parts. In some forms, the anatomic structures can be, but not limited to, any one of those described above, such as brain, liver, spine, prostate, heart, or gynecologic parts. In some forms, anatomic structures do not involve a breast. In a non-limiting example, a dedicated anatomy-specific magnet can be developed. These redesigns can be compared directly with the NuBo before finalizing a design and evaluating the MRI system in clinical applications. After determining a design with better performance compared to the NuBo, the design criteria and parameters of the prototype can be finalized for subsequent assessment of any safety concerns.

The MRI systems can be housed in clinical settings, and performance assessed in patient studies as well as assess ease of use in a clinical screening environment. FIG. 1E illustrates the open magnet for a non-limiting spine-specific application.

A goal of moving MRI out of the large hospital settings and into a community environment also includes simplifying the imaging process. While conventional MRI scanners have 100s, if not 1000s, of free parameters that can be chosen for each scan, the MRI systems can be designed with fixed protocols having a simple operation. The technologist would simply put the subject in position and execute instructions on a device (e.g., a hand-held device such as a tablet (e.g., iPad), mobile phone (e.g., a smart phone) or other hand-held devices) for scan 1, 2, 3, etc. Such a design allows for ease of use of anatomy-specific MRI in a community setting and even in diagnostic service centers such as Quest Diagnostics or CVS. New contrast mechanisms are available with field cycling as is diffusion contrast potentially leading to very short scan times. The model includes remote radiology reading of the scans through a radiology service. By ensuring identical scan protocols at all sites, this is a well-adapted scenario for artificial intelligence (AI) approaches to assisted reading³, and a very large data base could be acquired quickly—all with the exact same protocol, preferably for each type of anatomy.

There are multiple innovative aspects of the disclosed MRI systems and these range from the hardware to software, to how the data is ultimately used (AI assisted radiology). These developments are briefly reviewed in the following paragraphs.

### A. Magnet Design (Field-Cycling)

Using an electromagnet combined with field-cycling provides the freedom to design open MRI systems customized to specific imaging applications as in the disclosed anatomy-specific MRI system.

### A.1 Nonuniform B0 Magnet (NuBo)

We have already designed and built an innovative, open, field-cycling, electromagnet, for body imaging and proven the feasibility of this technology. Field-cycling provides two benefits in this context. First, we can use a relatively high field for spin polarization thereby avoiding the very low SNR problems of low-field systems. The second benefit is that by lowering the B0-field during the imaging part of the sequence (after a pre-polarization phase) we avoid the problems associated with field inhomogeneities, and this provides flexible magnet design opportunities allowing new open designs to be developed-such as those disclosed herein.

Our existing magnet (a nonuniform B0 system we refer to as NuBo) was designed to be built into a patient exam table for general body imaging applications in doctor's offices (FIGS. 1A-1D). This can be used for anatomy imaging in the prone or supine position, in that the highest polarizing fields encompass the anatomy of interest which should provide outstanding signal-to-noise, contrast and resolution. The NuBo magnet was built for generic applications, and as such needs improvements for improved anatomy-specific MRI. To enhance this system for anatomy-specific imaging two new developments are described herein: 1) The design of anatomy-specific transmit and receive RF coils, and 2) anatomy-specific spatial encoding gradients. These developments can provide high-resolution, high-SNR anatomy-specific MRI.

The existing NuBo system has a 3×3 flat panel set of array coils and relies on the Bloch-Siegert shift for spatial encoding. The geometry of specific organs in imaging applications, however, makes it possible to develop anatomy-imaging specific spatial encoding gradients (and RF) that allow for much higher spatial resolution and signal-to-noise ratio than exists with the current setup. NuBo's polarization field is oriented in the left-right direction. This polarization field creates a slice-selective magnetic field that varies in the anterior-posterior direction. To achieve spatial encoding, in a traditional Fourier encoding approach, separate gradients that achieve magnetic field variation in the left-right and superior-inferior directions can be developed.

Specific, non-limiting steps, include:
Wind gradient coils (shaped with a view toward the anatomy to be imaged).
Embed gradient coils in epoxy.
Connect coils to gradient cooling system.
Test gradient coil heating—repeat gradient system running at maximum power for readout time multiple
   times, measure temperature changes of coils, and temperature changes at specific anatomy's FOV.
Test gradient stability—repeat gradient system running at maximum power for readout time multiple times, measure stability of gradient field at multiple positions within the FOV.
Test duty cycle repeat gradient system running at maximum power for 2 ms readout multiple times.

### Transmit (Tx) and Receive (Rx) RF Coils for NuBo

The planar array we currently have on the NuBo system requires redesigning for improved anatomy-specific imaging. Therefore, we can replace this with volume coils that developed to encompass the specific anatomy.

It is contemplated that the developed RF coils yield high sensitivity. Our coil design choices rely on coil geometries that have been long-tested in conventional MRI but here, customized for low field nonuniform MRI, to achieve optimal SNR/homogeneity performance in analog to the conventional field strength using a transmit-only/receive-only (TORO) configuration (Barberi, et al., An Official Journal of the International Society for Magnetic Resonance in Medicine 43, 284-289 (2000)). The designs also account for nonstandard and spatially varying orientation of the magnetic field, which leads to a need to detect precession of spins in nonstandard and spatially varying planes.

### New Volumetric Tx/Rx Solenoid Coil

For some anatomy, a solenoid coil can be designed and/or improved using EM Simulation and Optimization. The solenoid structure can be modelled using CST (Dassault Systems Deutschland GmbH), following previously reported optimization strategies (Sun, et al., Magnetic Resonance Imaging 11, 73-80 (1993); Koonjoo, et al., in Proceedings of the 31st Anmial Meeting & Exhibition of the International Society for Magnetic Resonance in Medicine (ISMRM) (Toronto, Canada, 2023), p. program number 3895).

Specific, non-limiting steps, include:
Development and Bench Testing. The improved solenoid can be built and tested on the bench, including B1+ mapping to verify with the simulation, using the bench mapping system developed in the lab.
Scanner Testing. The solenoid can be tested and used on scanner as a Tx/Rx coil, measuring B1 amplitude and uniformity as well as flip angle per unit input power.
A custom-shaped volumetric Tx/Rx solenoid RF coil for anatomy-specific imaging on the NuBo system can be developed. A more advanced parallel Rx version can be constructed in Phase 2 if we move ahead with the NuBo system.

### Integration to Complete NuBo

The rest of the NuBo system is built and can easily accommodate these spatial encoding gradients and new RF coil designs. Similarly, we have implemented active electromagnet interference (EMI) sensors to detect noise and subtract this from the MRI signal such that imaging can be performed in the absence of an RF shielded room (making siting much easier than for conventional MRI systems). We can use a suitable console, such as our existing Tec-Mag console, for this work.

### A.2 Dedicated Anatomy-Specific Magnet

The NuBo system was built as a general MRI system for body imaging and designed to be built into an exam table with capabilities of performing cardiac, spine, and liver imaging, in addition to breast imaging. The design criteria to produce an anatomy-specific MRI device are different, however. An innovative new design can be developed based on the same field-cycling principles. This system can generate a higher polarization field than NuBo (and hence more signal) because of the tailored shape of the magnet. Tests can be performed to determine whether this dedicated-anatomy-magnet can be built with a smaller footprint, lower cost, and yet provide a higher, more uniform polarizing field for maximizing signal compared to the NuBo system with anatomy-specific gradient and RF hardware.

### A.2 Local Gradient Coils

By designing local gradient coils that surround an anatomy of interest, we can achieve high spatial resolution with low-cost gradient coils and amplifiers. Slice selection with our field-cycling magnet is performed by adjusting B0, and then in-plane spatial encoding is performed using local gradients and receivers. The designs of our unique gradient systems are innovative and tailored specifically to the B0 field produced by the field-cycling magnet.

### A.3 Local Transmit and Receive RF Coils

The disclosed approach to RF is innovative in that custom coils are designed complementary to the B0 main magnet. Receive-only array coils for accelerated parallel imaging can also be implemented in the MRI systems. Parallel receive coils could provide advantages in SNR and accelerated acquisitions (Hancu, et al., Magnetic Resonance in Medicine 75, 897-905 (2016); Hancu, et al., Journal of Magnetic Resonance Imaging: JMRI 36, 865-872 (2012); Sodickson & Manning, Official journal of the Society of Magnetic Resonance in Medicine/Society of Magnetic Resonance in Medicine 38, 591-603 (1997); Pruessmann, et al., Official journal of the Society of Magnetic Resonance in Medicine/Society of Magnetic Resonance in Medicine 42, 952-962 (1999)) (particularly relevant for dynamic contrast enhanced (DCE) imaging) further enhancing our system. Suitable arrays, can be implemented. These RF coils reflect innovations necessary to image in these non-standard magnetic fields.

### A.4 Console

While our initial systems can use commercially available Tec-Mag Redstone consoles, we can develop a low-cost console similar in nature to the OCRA open-MRI consoles currently available (Anand, et al., Proc Intl Soc Magn Reson Med Paris (2018); Takeda, Rev Sci Instrum 78, 033103 (2007); Feng, et al., IEEE Transactions on Biomedical Engineering 59, 2152-2160 (2012); Stang, et al., IEEE Transactions on Medical Imaging 31, 370-379 (2011); Dalal, et al., Conf Proc IEEE Eng Med Biol Soc 2006, 1897-1900 (2006)). To purchase a console from a major manufacturer can cost 100's of thousands of dollars. Yet it has been shown that programmable circuit boards can be used to develop controller hardware for MRI systems for less than $1000. Following the developments from the open-source console group (OCRA) (Anand, et al., Proc Intl Soc Magn Reson Med Paris (2018)) a field programmable logic (using Verilog (IEEE Standard for Verilog Hardware Description Language. IEEE Std 1364-2005 (Revision of IEEE Std 1364-2001), 1-590 (2006)) programming) can be used as the basis for a console for our system. This can be interfaced with iOS iPad using the Apple Swift code for open-source development, representing another innovation.

The console controls the pulse sequences, which control the polarizing field, the spatial encoding gradients, the RF, and the data acquisition boards. It controls the timing of the transmit radio frequency (RF) pulses through the hardware and receives and processes signal from the hardware to generate images. Commercially available MR consoles, like TecMag's Redstone, are high performing but also inflexible, expensive, and technically opaque. As a result, many ‘homemade’ consoles (Mehring, et al., Phys Rev A Gen Phys 33, 3523-3526 (1986); Sacolick, et al., Official Journal of the Society of Magnetic Resonance in Medicine/Society of Magnetic Resonance in Medicine 63, 1315-1322 (2010); Lang, et al., The Lancet Oncology 24, 936-944 (2023); Oeffinger, et al., JAMA-Journal of the American Medical Association 314, 1599-1614 (2015); Siu, Annals of Internal Medicine 164, 279-296 (2016); Hollingsworth, The American Journal of Surgery 218, 411-418 (2019)) have been designed which offer a more configurable, low-cost design to accommodate research and development applications. For this purpose, field programmable gate arrays (FPGA) have become popular in console design because they are reprogrammable and can process data in parallel making them flexible and well suited for the requirements of MRI. While FPGA based consoles have been designed previously to improve console performance (Mehring, et al., Phys Rev A Gen Phys 33, 3523-3526 (1986); Sacolick, et al., Official Journal of the Society of Magnetic Resonance in Medicine/Society of Magnetic Resonance in Medicine 63, 1315-1322 (2010)), many designs revolve around a central data bus and thus lack scalability. However, many research and commercial MR applications demand that consoles can handle multi-channel parallel transmit/receive RF and data acquisition systems. Existing implementations of multichannel consoles split the RF signal generated on a single FPGA equally into vector modulators for each channel (Lang, et al., The Lancet Oncology 24, 936-944 (2023); Oeffinger, et al., JAMA-Journal of the American Medical Association 314, 1599-1614 (2015)). While this design allows for a scalable design, it lacks flexibility because all channels must operate at the same frequency and use the same pulse sequence. The Medusa console (Stang, et al., IEEE Transactions on Medical Imaging 31, 370-379 (2011)) offers a modular design with individual channel control of frequency and timing but uses analog RF hardware which is not ideal. There is another scalable console which solves this by using entirely digital hardware (Dalal, et al., Conf Proc IEEE Eng Med Biol Soc 2006, 1897-1900 (2006)), but it only includes the receive path and thus has no pulse sequence design. We can combine these innovations to develop a completely modular FPGA based console, allowing a scalable number of independently controlled transmit and receive channels to be configurable to new developments in MR hardware and pulse sequences.

### Complete the HDL Programing for Controller, Magnet Control, and Tx/Rx Boards

A block diagram level schematic of the logic distribution across the components of the console has been developed as shown in (FIG. 5). This modular design results in the most flexible console, as well as the least expensive console because the FPGA work is shared across several boards to avoid one large, expensive FPGA. To expedite this step, we can maximize the use of open-source hardware description language (HDL) code as possible from. The transmit (Tx), receive (Rx), and waveform generator logic can be identical to these previous open-source projects as it already has been proven to be effective. The data path from the controller board to the peripheral boards (magnet control and each Tx/Rx) is new. A controller sequencer HDL program can be created which can send the individual channel pulse sequence to each applicable board serially. Updates to the sequencer logic for the Tx/Rx boards and magnet control boards can add an additional control step so sequences are not executed until an additional command is received from the controller board. Thus, each peripheral board is executing independently, increasing the modularity of the design. On the receive path data can flow to each Tx/Rx board for initial storage data until it receives a command from the control board requesting the data to limit parallel processing power needed from the controller board. Once completed, all HDL modules can be made available via GitHub. The resulting design can be easily scalable to as many channels as the number of outputs on the controller board allow. The original design can accommodate up to 32 transmit/receive channels for the RF.

### Build a Prototype of the Console

Starting from the block diagram and system level requirements for the console, all hardware requirements can be derived. This step can include configuration of the size of the FPGAs to minimize cost and size of the system as well as decisions about the specific FPGA chips and other hardware that can be used. This step can finalize the number of channels per board. An online schematic tool-Digi-key's “Scheme-it” can be used to create the circuit schematic. We can then build a simplified prototype of the console with evaluation board versions for each of the components. Initially, we require only a two Tx/Rx boards as opposed to the full 32 channel Tx/Rx design. This can be simple to build and easy to troubleshoot. This can be sufficient to test the modular logic and timing of the design. The hardware and logic design can be evaluated using this prototype.

### Pulse Sequences and User Interface

Our pulse sequences can be ported from a console (such as the TecMag console) to an alternative low-cost console. The software for the user interface can also be developed and we envision this to be developed on a device (e.g., a hand-held device such as a tablet (e.g., iPad), mobile phone (e.g., a smart phone) or other hand-held devices). The user interface can have only very limited control-allowing the user to start and stop a study or scan, and to select which pulse sequence to run from a fixed order menu. In addition to prompting for each scan it can include prompts to begin contrast injection. Preferably, none of the pulse sequence parameters will be available for modification by the users unlike on conventional magnets. This ensures that the proper protocol is always applied, and data consistency is maintained to facilitate machine learning and/or deep learning AI assisted radiology.

A.5 System Developments Herein that are Applicable to Many B0 Geometries

### Pulse Sequences

Field cycling introduces new contrast mechanisms and because a polarization period must be added to each sequence many new aspects must be introduced to utilize this technology. We describe below the development of T1-weighted, T2-weighted, and dynamic contrast enhanced imaging, sequences to integrate with our field cycling system. We also include fat saturation and new developments in diffusion imaging as a component of MRI exams. Two major innovations on the pulse sequences side include the use of B0 field-cycling for generating strong diffusion weighting with very short Time to Echo (TE), and the reversal of the polarizing field during the initial polarization period for nulling the signal from fat (or other tissue present in the sample/volume of interest).

Conventional pulse sequences and contrast mechanisms can be accessible with the disclosed MRI systems. The described protocols closely match those used at standard clinical settings with 1.5 T and 3 T. This includes T2-weighted turbo-spin echo, diffusion weighted imaging (DWI), T1-weighted TSE (pre, dynamic T1, and post contrast administration to look for late enhancement) (Mann, et al., Radiology 292, 520-536 (2019)). Our target resolution can be a slice thickness of 2.5 mm and in-plane resolution 1 mm2 (Mann, et al., Eur Radiol 18, 1307-1318 (2008)). While this can be developed for in vivo application, our target contrast can have a max dose of gadobenate dimeglumine 0.1 mmol/kg of body weight (Pediconi, et al., Am J Roentgenol 191, 1339-1346 (2008); Carbonaro, et al., Am J Roentgenol 196, 942-955 (2011)) with power-injector 2 mL/see flushed with 20 mL bolus saline. We can use fat suppression and explore DWI, while maintaining short TE. This is possible because our magnet can produce a very large gradient (b-values even over 1.4×10−3 mm2/sec8) in a short encoding period minimizing TE and maximizing signal.

### T1-Weighted and T2-Weighted Imaging

Both T1- and T2-weighted sequences can be turbo-spin echo sequences for minimizing scan time. T1-weighted sequences are very useful in lesion detection (Kuhl, The British Journal of Radiology 91, 20170441 (2018); Kuhl, Invest Radiol 50, 615-628 (2015)) and also serve as the baseline image prior to contrast agent administration. The T2-weighted images can reduce the number of false-positives. We can perform T2-weighted imaging both with fat suppression (fluid intensity is intensified) and without fat suppression (quality of tissue architecture and lesions morphology is enhanced).

We can implement a T1-weighted turbo-spin echo pulse sequence for dynamic contrast enhancement studies with a maximum acquisition time of 100 s and repetitions for up to 6 minutes post-contrast injection. Our target resolution can be a slice thickness of 2.5 mm and in-plane resolution of 1 mm².

### Contrast-Enhanced Sequence Development

To maximize the T1-imaging capabilities, we can use gadobenate dimeglumine which has an in vivo T1 relaxivity that is twice the T1 of the widely used contrast agent gadopentetate dimeglumine (Luciani, et al., Research and Reports in Nuclear Medicine 5, 33-40 (2015)). We can use a maximum dosage of gadobenate dimeglumine 0.1 mmol/kg of body weight (Lo Gullo, et al., European Radiology 32, 6588-6597 (2022); Bickelhaupt, et al., Journal of Magnetic Resonance Imaging 46, 604-616 (2017)) with power-injector 2 mL/sec flushed with 20 mL bolus saline. Images can initially be acquired prior to IV injection and then 100, 200, and 400 seconds post-injection, though optimal timing can be determined experimentally by acquiring images with high temporal resolution in 4 subjects with known pathology. The endpoint of this task is to implement a serial multi-phase acquisition with short acquisition time in our T1w acquisition such that images can be acquired prior to IV injection and then 120-, 240-, and 360-seconds post-injection.

### Field Inversion for Nulling Fat or Water

Field cycling also can be used to exploit T1 contrast as the polarization accumulates at the rate of T1. T1 contrast increases at low field, increasing the selectivity of this approach (Hori, et al., Invest Radiol 56, 669-679 (2021)). Experimental data how reversing the polarization field direction with a variable duration acts much the same way as conventional inversion recovery imaging allowing the contrast between two different T1 species to vary as a function of negative- or positive-polarization time. Preliminary data indicates that this provides, a T1 dependent polarization curve for each spin species, rather than the conventional T1 relaxation curve.

### Diffusion Weighting

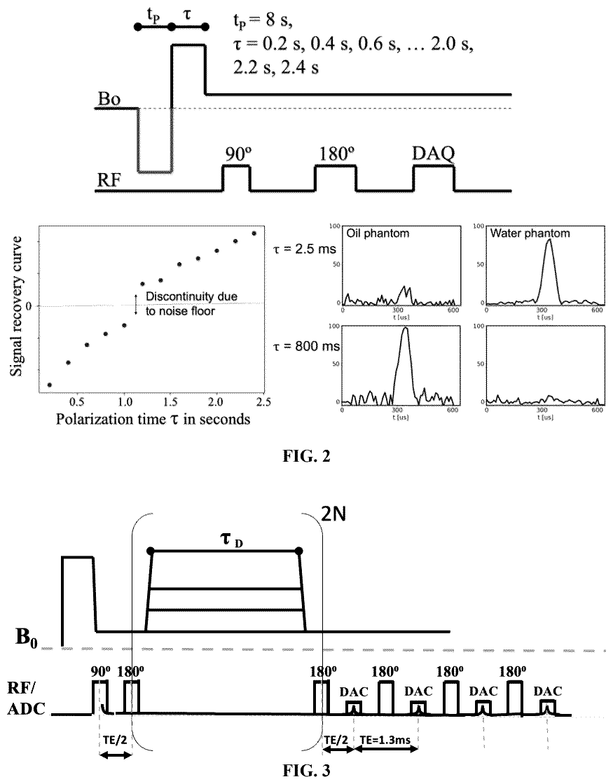

Diffusion-weighted imaging, unlike other conventional contrast imaging, has high sensitivity to the detection of changes in the cellular environment without the need for intravenous contrast material injection. While the spatial encoding gradients and echo spacings during readout at 24 mT provide little diffusion weighting (b<2 s/mm²), strong gradients are available from the main B0 magnet. The pulse sequence diagram in FIG. 3 shows an innovative approach we have developed to use this capability to provide a diffusion weighting preparation module. Preparation echoes can encode diffusion with gradient amplitudes >600 mT/m. This encodes b˜6000s/mm² with one pair of 7 ms pulses, providing very strong diffusion weighting while maintaining short TE for maximum signal. Note that higher b-values have been shown to improve lesion conspicuity (Bickelhaupt, et al., Radiology 278, 689-697 (2016); Stadlbauer, et al., European Radiology 19, 2349-2356 (2009)).

Diffusion weighting can also be increased by applying serial shorter diffusion encodings (i.e., N>1 in FIG. 3). Notably, the field (and gradient) during diffusion encoding can be either higher or lower than the 24 mT readout gradient, so b-values as low as 5 s/mm² can be encoded over the fixed echo time. Encoding multiple diffusion weights at constant echo time aids quantitative data models. With appropriate timing, a refocusing pulse train can directly begin the readout and spatial encoding. In addition, multiple modules can be inserted within the echo train, potentially yielding data at multiple b-values in each repetition time (TR).

### Image Reconstruction Software

Reconstruction algorithms can be customized to accommodate the spatial encoding and data acquisition schemes that arise from different gradients and RF. Note that we do not use standard Fourier based image reconstruction because that cannot accommodate the nonlinear spatial encoding fields that are used for spatial localization. We have extensive experience with spatial encoding using nonlinear gradients and some of the efficiencies that this brings to encoding (Tam, et al., Magnetic Resonance in Medicine 73, 2212-2224 (2015); Tam, et al. Magnetic Resonance in Medicine 68, 1166-1175 (2012); Tam, et al., Magn. Reson. Med 51, 172 (2004); Stockmann, et al., Magnetic Resonance in Medicine 64, 447-456 (2010); Stockmann, et al., Magnetic Resonance in Medicine 69, 444-455 (2013); Stockmann, J. P. & Constable, R. T. in Proc. Intl. Soc. Mag. Reson. Med. 2857; Galiana, et al., Concepts in Magnetic Resonance. Part A, Bridging Education and Research 40a, 253-267 (2012)).

### Eddy Current Corrections

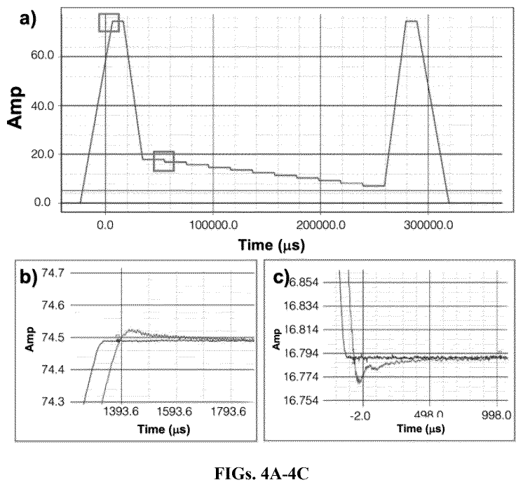

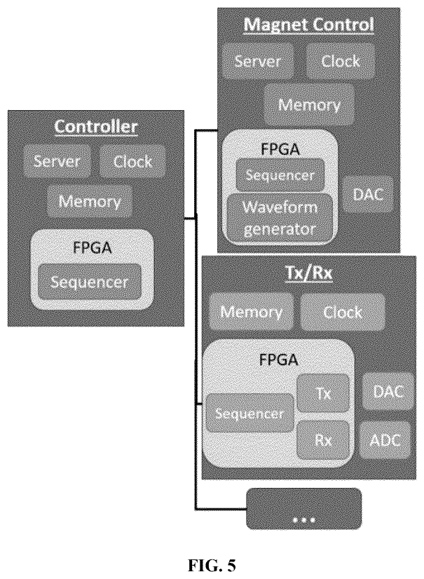

The polarizing magnet used in both NuBo and DBM is essentially a very high-powered gradient, and as such, sophisticated corrections like those used in traditional gradients are possible and appropriate. One potential concern is eddy currents, i.e., fields associated with currents induced during switching. Our measurements from a simple trapezoidal input waveform shows short stabilization times when ramping down from polarization to imaging field on the NuBo system (see FIGS. 4A-4C). However, measuring gradient impulse response functions (GIRF) in strong nonlinear gradients can be done, and standard methods work well. We have verified that GIRF characterization of nonlinear gradients can provide successfully pre-emphasized waveforms (Hoque Bhuiyan, et al., Medical Physics 48, 5804-5818 (2021); Fettahoglu, et al., Proc. of ISMRM, 4431 (2023)). For eddy currents associated with diffusion imaging, modern eddy correction post-processing techniques used for DWI image processing already model the eddy currents with a nonlinear basis, and these techniques are also effective (Andersson, et al., NeuroImage 125, 1063-1078 (2016)).

### Concomitant Gradient Corrections

Concomitant terms from spatial encoding gradients are another important consideration. During the low readout field, even weak spatial encoding fields can have non-negligible amplitude compared to the static magnetic field. Therefore, components perpendicular to the main magnetic field contribute to the Larmor frequency and must be factored into the phase evolution (Volegov, et al., Journal of Magnetic Resonance 175, 103-113 (2005)). Fortunately, our calibration approaches can provide spatially (and temporally) resolved measures of B_{LR}, B_{SI}, and B_{AP} for both the main field and the spatial encoding fields, so corrections associated with concomitant fields are straight forward to calculate and these can be incorporated into the encoding matrix for reconstruction. Our reconstruction algorithms can be extended to include the effects of concomitant fields. The effect of concomitant fields can be estimated from initial measurements of the magnetic field in polarizing and gradient hardware. These can be incorporated into encoding matrix to properly model phase evolution during spatial encoding. Initial reconstruction algorithms can use GPU-accelerated algebraic reconstruction to provide maximum flexibility so that all hardware characterization can be accurately incorporated into the encoding matrix.

It is contemplated that the reconstruction time and implementing denoising and regularization can be improved via machine learning. Since our data can be collected with identical imaging protocols, we can rapidly accumulate a large, annotated set of images that can enhance the performance of deep learning strategies for artifact reduction and image quality improvements. We can also develop software to subtract the pre- and post-contrast images to generate maximum intensity projections for rapid lesion detection (Mango, et al., European Journal of Radiology 84, 65-70 (2015); Kuhl, et al., Journal of clinical oncology: Official Journal of the American Society of Clinical Oncology 32, 2304-2310 (2014)).

### Compare NuBo and Dedicated Anatomy-Specific Magnet Prototypes and Choose the Best System

Data from human and phantom studies can be analyzed for polarizing field, field uniformity and coverage (including chest wall and axillary regions) gradient strength, resolution, SNR, contrast, and stability. The best preforming scanner on these metrics (with maximum weighting given to resolution and SNR (since many factors such a field uniformity, polarization strength and gradient strength combine in these summary measures of SNR and resolution)) can then be further developed for deployment in a clinical environment and subsequent clinical efficacy studies.

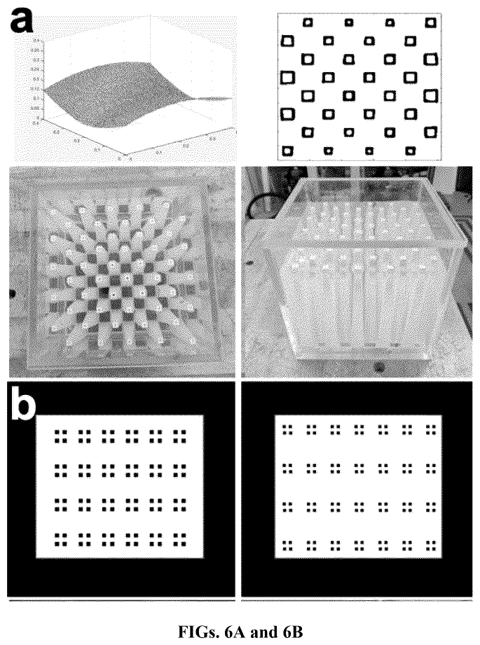

We have constructed a pyramid phantom (FIG. 6A) that provides a useful shape for quantifying image sharpness across the field-of-view as well as for measuring the slice profile. Our slices are non-planar and thus the size of the squares in the image allows us to calibrate the slice profile (as measured vertically from the flat surface of the magnet) as a function of position in the FOV. Using this phantom, we can calibrate slice profiles and measure the sharpness across the FOV. Quantifying sharpness of the gradient along each of the 4 edges of each pyramid, provides a 2D view of sharpness throughout the FOV. Signal can be measured between every pair of pyramids and then fit to a smooth surface to yield SNR across the FOV. We can also use a series of three small contrast detail phantoms (two are shown in FIG. 6B) constructed of a plexiglass box with vertical square rods in sets of 4 with 3 mm skip 3 mm (in one phantom), 2 mm skip 2 mm (in another), and 1 mm skip 1 mm rod placements (in a 3rd phantom). These phantoms can provide a measure of spatial resolution across the FOV. Each phantom study can be repeated three times to provide an average value for each metric. The endpoint is to resolve the 2 mm rods with at least 50% contrast. Improvements of pulse sequence parameters, views, timing, number of encodings per polarization period can be performed in phantoms. These improvement studies serve to maximize image quality with depth, contrast, and SNR.

A set of contrast phantoms can also be developed to assess adequate contrast is achieved for each pulse sequence. All phantoms can be designed to cover the FOV of an anatomy of interest. The phantom used to assess T1 contrast can contain vials doped with gadobenate dimeglumine to mimic relaxivities observed in vivo. Similarly, a phantom for T2 contrast can contain multiple concentrations of MnCl2, a phantom for diffusion contrast can contain multiple concentrations of PVP, and a phantom for fat/water suppression can contain vials of oil and water.

Each scan optimized in phantoms can also be tested on healthy volunteers. These images can be examined for perceived artifacts and appropriate contrast in the specific anatomy. These studies can also be used to inform appropriate protocols for human scanning, including ergonomics.

Spatial resolution as a function of encoding strategy is our primary outcome measure and thus the best acquisition strategy can be that with the best average resolution (as measured using the contrast detail phantom) over the 16×16 cm2 FOV. Strategies that also yield excellent SNR, and image sharpness can be preferred after resolution is maximized. Contrast is assumed to be highly similar in NuB0 and dedicated anatomy-specific magnet scanners, but discrepancies can be quantified and taken into consideration. In addition, scans from healthy human testing acquired during method development can be reviewed by radiologists on our team and rated on a Likert scale for overall image quality to ensure that the system yielding highest resolution is also the one found to have highest clinical quality.

### A.6 MRI Siting, Installation, and Operations

Imaging sites (ranging from clinics to franchises such as CVS or Quest Diagnostics) would provide retail space for the exams, etc. Secondly, all the data can be routed to a central reading resource where radiologists perform the read. This has two primary advantages: i) the community sites do not require radiologists; ii) the standardized data from many sites rapidly creates a large training set for machine learning and/or deep learning AI radiology applications focused on AI-assisted radiology (Lang, et al., The Lancet Oncology 24, 936-944 (2023)), such that ultimately many cases can be read quickly by few radiologists further decreasing costs.

Also contemplated are additional developments that could incorporated in extensions of these MRI systems, which facilitate different applications. For example, both the magnet and the RF can be swapped out for imaging different anatomic structures, but with the same amplifiers, chiller, and other components. A prostate imaging saddle shaped magnet is envisioned for prostate screening and dedicated extremity systems for imaging the wrist or ankles could also be envisioned-all connected to the same base hardware. Where these swappable front ends were in different rooms, the MRI systems can be used in a multiplexed fashion across rooms greatly saving costs on amplifiers and other components.

### III. Methods of Using

Also disclosed are methods of imaging a sample/volume of interest of using the MRI systems described herein, the methods involving field cycling between the first non-uniform B₀ magnetic field and the second non-uniform B₀ magnetic field. The first non-uniform B₀ magnetic field is applied to the sample/volume of interest prior to applying the second non-uniform B₀ magnetic field to the sample/volume of interest, and field cycling between the first non-uniform B₀ magnetic field and the second non-uniform B₀ magnetic field is achieved by controlling/altering a current supplied to the magnet. RF coils can be used to generate spatial gradients, to select a non-planar isofield slice, and receive mode (e.g., parallel receive mode) to detect magnetic resonance signals. Each of these tasks can be performed using either the same or different subsets of RF coils. DC nonlinear gradients can be used for spatial encoding, either with or without the addition of RF encoding and/or receive mode (e.g., parallel receive mode). MRI images are reconstructed from (potentially parallel) received magnetic resonance signals from RF coils using algebraic reconstruction, preferably without the use of standard Fourier-based image reconstruction. Preferably, the MRI systems are designed for specific applications in imaging the brain, breast, liver, spine, prostate, heart, or gynecologic applications. Preferably, the MRI systems are designed for specific applications in imaging the brain, liver, spine, prostate, heart, or gynecologic parts. Preferably, the MRI systems are designed for specific applications that do not involve breast imaging.

A centralized reading service with standardized protocols can also rapidly generate very large data to facilitate the training AI algorithms (Hosny, et al., Nature Reviews Cancer 18, 500-510 (2018); Sharma, et al., Journal of Thoracic Imaging 35, S11-S16 (2020)). It is believed that in the coming years radiology will see a large push to standardize protocols to take advantage of new developments in machine learning and/or deep learning assisted radiology.

For 50 years, the steady trend in MRI technology has been towards higher field and more sophisticated (read: more costly) equipment. However, thanks to the many technological advances realized in that time (e.g. major developments in hardware design, spatial encoding, image reconstruction), it has become feasible to design extraordinarily low-cost and accessible MRI hardware with high clinical utility. These systems have potential to disrupt the field and make MRI available in a wide range of settings, including neighborhood clinics, rural communities, and underdeveloped countries.

To date, most of the designs costing less than $500 k have several common features. They use arrays of permanent magnets arranged around a cylindrical former to generate a relatively homogeneous B0 field in the center. Because of the limitations of this design, it is difficult to achieve more than ˜65 mT. In addition, the homogeneous imaging volume is limited to the center of that cylinder. Most of these systems also use conventional image encoding strategies, namely linear gradients for slice, frequency, and phase encoding³⁵⁻³⁸. Several low field MRI designs have been demonstrated, both in research and commercially, for brain imaging. A single sided low-resolution MRI, suitable for image fusion in biopsy guidance, has also been developed for prostate. However, there are currently no instruments being developed for accessible MRI. Equipment that facilitates affordable MRI is key to making MRI a routine modality for either screening or supplemental imaging.

Because the additional vasculature needed for a tumor to grow beyond 2 mm is often leaky, contrast enhanced-MRI (CE-MRI) is uniquely sensitive to aggressive and clinically significant tumor types. However, non-contrast methods such as diffusion weighted imaging (DWI) have found an increasing role (Martincich, et al., European Radiology 22, 1519-1528 (2012); Lo Gullo, et al., European Radiology 32, 6588-6597 (2022); Bickelhaupt, et al., Journal of Magnetic Resonance Imaging 46, 604-616 (2017)). Whereas CE-MRI highlights vascular features of lesions, DWI provides specificity to the hindered diffusion associated with proliferative pathologies. Adding DWI to anatomy-specific MRI protocol, especially a high b-value image, dramatically increases specificity (Saccenti, et al., Diagn Interv Imaging 104, 410-418 (2023); Pinker, et al., Invest Radiol 53, 587-595 (2018)). It may also have value as a standalone exam that avoids contrast injections. Results from non-contrast studies (diffusion and T2w imaging) showed equivalent sensitivity and specificity 50 to CE-MRI, albeit with reduced lesion visibility.

### IV. Methods of Making

The disclosed MRI systems can be produced and tested in one or more phases described below, with an important endpoint being the development of low-cost MRI systems for wide-spread screening, diagnoses, and/or monitoring of specific anatomic structures, e.g., for screening, diagnoses, and/or monitoring. These MRI systems would greatly increase access to this important modality.

### Phase 1: Hardware Development Phase

We have an existing low-cost, field cycling magnet that works. The Phase 1 process chiefly includes developing anatomy-specific spatial encoding gradients and RF transmit/receive coils to enable the existing system to perform at high-resolution with high-SNR. This is referred to as the nonuniform B0 (NuBo) magnet. The B0 field direction for this system is in the Left/Right direction, relative to a patient laying prone on the magnet, which requires custom gradient and RF designs.

With the knowledge gained from the development of the NuBo system magnets with geometry appropriate for different applications can be developed, such as a dedicated anatomy-specific magnet. The primary B0 field direction for this magnet is Anterior/Posterior (vertical with respect to a patient laying on top of the magnet).

A first endpoint is to complete construction of these two systems in Phase 1 and directly compare them in terms of cost-to-build, polarizing field profiles, gradient and RF performance across the field of view, and signal-to-noise ratio.

The next step in Phase 1 involves completion of the development of common elements including pulse sequences, console, electromagnetic interference (EMI) correction system, and reconstruction algorithm (e.g., image reconstruction algorithm). Whether we move forward with the NuBo or DBM system, there are common elements that must developed, and these include the pulse sequences, the low-cost console, noise cancelation hardware/software so the devices can work outside of a shielded room (again to ease siting and reduce installation costs), and the reconstruction algorithm designed for acquisitions with nonlinear spatial encoding.

Another step in Phase 1 involves selecting a magnet design with improved performance for anatomy-specific MRI.

Following completion of the NuBo and dedicated anatomy-specific magnet prototypes, we can directly compare these systems to determine which one provides better performance for moving forward. The comparison can focus on the polarizing field strength and distribution, imaging performance characteristics, such as SNR, field cycling (stability and speed of ramping up and down), heating, and cost. If the NuBo system is the winner in this comparison, then we can construct a 2^{nd} generation NuBo2.0 magnet, designed and enhanced based on what we have learned so far. NuB02.0, which is designed to provide better polarization, particularly at the chest wall, and provide better ergonomics in terms of access. We can test this new design against NuBo1.0 and the dedicated anatomy-specific magnet but are confident it can outperform NuBo1.0 (which would have already outperformed the dedicated anatomy-specific system). The purpose of this design is to redesign the magnet to be more open and customized to the shape of the anatomic structure, producing a higher field and easier access/comfort for the patient. If the dedicated anatomy-specific magnet proves to be superior, then we can further develop that design. This is expected to be the only deviation from the prototype unless there are other design modifications that we discover are necessary from the first prototype.

Dependent upon the outcome from the comparison of NuBo and dedicated anatomy-specific, the next step can be to construct the first clinical prototype and finalize design criteria prior to making additional systems for testing in the clinical environment. Prior to building the 2nd and 3rd magnets for installation in clinics we can do final testing of this first clinical scanner, installed at a patient-only room in the Yale MRRC. We can proceed by imaging 10 healthy subjects in both the prototype and first clinical system. In the unlikely event that image quality is lower than that observed in the prototype, an exact replica of the winning prototype (either dedicated anatomy-specific or original NuB0 for prone imaging) can be built for installation in clinical sites. Our measurable standards are that the first clinical scanner at a minimum matches performance of the prototype. It is contemplated that this version of the scanner can outperform the original.

### Phase 2: Finalizing Design and Manufacturing Phase

One aspect in Phase 2 would involve defining manufacturing processes for finalized design and building a clinical scanner. Phase 2 focuses on finalizing the overall system design, including the operating software, reconstruction software and all hardware components. This can also include the software for the user interface, safety checks on pulse sequences and the ergonomics of the patient table. Software development can follow an Agile development process based on AAMI TIR 45 which in turn is compatible with the international software standard IEC 62304 (AAMI, A. Association for the Advancement of Medical Instrumentation 21, 22-78 (2012); (IEC), I. E. C. IEC 62304 Medical device software—Software life cycle processes [Internet]. Geneva, CH; (2006)). Optionally, once the protype design has been finalized this can allow us to engage the FDA in formalizing the construction, quality assurance steps, manufacturing process, and safety. Optionally, the first scanner can be built and validated with well-defined and documented processes in expectation of FDA filing. Careful documentation of all manufacturing, both for the first and subsequent clinical scanners, can be gathered for commencement of the FDA process. This also necessitates formalizing all manufacturing steps and putting in place procedures that ensure quality control in every step of the manufacturing process. Following these steps, we can build two additional systems to be installed in satellite imaging clinics. During this time the technicians on site can be trained to operate the scanner, including all safety aspects, and data archive and transfer steps. The technicians can also be trained to run daily QA procedures on this system—usually at startup in the morning each day.

Another aspect in Phase 2 optionally involves completion of FDA eligible prototypes and clinical implementation. Following validation of the first clinical device, we can build subsequent clinical scanners following the same manufacturing and acceptance procedure. A major step in bringing a new device to clinical use involves engagement of the FDA to begin the process of obtaining FDA approval. The FDA regulates medical devices to assure their safety and effectiveness and this process begins with carefully outlining each component of a complex device, and how it is manufactured in a manner that ensures quality control, both of each component and of the overall device. This milestone completes the initial steps which include the conclusion of device discovery and the construction of a preclinical research prototype. The FDA classifies MRI devices as Class II (moderate risk) medical devices, and thus a 510(k) approval must be sought prior to marketing such a device (Van Norman, JACC: Basic to Translational Science 1, 277-287 (2016)). Achieving this milestone means can begin this process with our anatomy-specific MRI systems. In addition to collecting data on clinical efficacy of how these systems work, it is first important to install such systems in a clinical environment, such as a mix of academic imaging centers and community imaging clinics.

Another aspect of Phase 2 involves completion of sequences and/or software for monitoring safety and/or for quality assurance. Safety protections can include real-time detection and control of dB/dt, SAR, and temperature for all relevant components. The input from these monitoring components can be interfaced directly to the console to prevent operation outside the safety guidelines. In addition, we can develop a QA protocol to be run on a standard phantom, with automated acquisition and analysis. This can be used to confirm proper operation of all hardware components either on a daily or as-needed basis.

Permanently connected magnetometers can be installed at the edge of each magnet. These, in combination with previously acquired 3D maps, can be used to monitor field stability across time and to prevent scans that may produce PNS. Notably, the maximum slew rate of our systems (˜0.5 T in 35 ms) is still well below the cardiac stimulation limit, which itself is set conservatively by about an order of magnitude. B1 can be similarly monitored using a sniffer coil placed outside the FOV and, in combination with previous measurements, can be used to monitor SAR in real-time. These, as well as temperature monitors for all electromagnets can be interfaced to console which can monitor this input to prevent scans that violate safety limits. It is contemplated that the scanner can automatically detect and prevent scans that violate prescribed dB/dt, SAR, or temperature limits.

A daily scan protocol can be established to confirm proper system function at the start of each day's operation. These scans can be run on a standard resolution phantom with standard positioning, so that images can be automatically assessed. Analyses can confirm that all hardware is within specifications including polarizing field strength, gradient shape, RF power, and receiver SNR. EMI functionality can be confirmed via a scan that excludes signal excitation. The console can run this series consecutively and analyze the data, so no user interaction is required, beyond starting the procedure. If service is needed, the system can automatically send the results to us for troubleshooting. It is also contemplated that scanner can perform scan series and analyzes data in an automated manner. Aside from positioning the standardized phantom and beginning the procedure, no further interaction should be required.

Data collected for safety monitoring, along with environmental variables, can be accumulated in tandem with the daily QA scans. This data can be assembled and mined to identify patterns between QA image metrics and hardware variables. It is further contemplated that contemporaneous data, both images and monitored variables, from all sites can be available and searchable.

Another aspect of Phase 2 optionally involves further advances in SNR and speed. In parallel with system manufacturing, we can test the utility of multichannel phase arrays to implement parallel imaging which can improve scan time. Once clinical data are being acquired through clinical use, we can also test methods to leverage both imaging data and calibration scans to further improve system performance and image quality.

Designs are presented for both the NuBo and dedicated anatomy-specific systems. However, coils (RF and gradient coils) are different because these two systems have the polarization field B0 pointing in different directions therefore necessitating different designs.

### Develop Parallel Receive Array Coils for Accelerated Imaging

NuBo parallel Rx: Parallel receive coils can exhibit improved SNR along the periphery of the FOV and allow accelerated acquisitions through reduced sampling. The subtasks of developing a suitable array coil are listed below:

EM simulation and component value calculation. The array structure can be EM modelled using CST (Dassault Systems Deutschland GmbH). A decoupling network with an appropriate network architecture can be firstly calculated based on the simulated coil loss/inductance/mutual inductance.

Bench development and decoupling improvements. The proposed array coil can be built on bench, and the decoupling network between each element can be developed and improved upon. Both ladder-network and transformer decoupling can be investigated. The winner of the two can be used on the final version of the array coil.

Detuning circuits. TORO configuration requires the Tx coil and the Rx coil to be well decoupled, and this is mostly achieved by detuning one of the two at different Tx or Rx windows. Conventional RF switch design using PIN diodes was found to be too slow for our application, but metal oxide semiconductor field effect transistors (MOSFETs) have been reported to be a good alternative (Nacher, et al., Journal of Magnetic Resonance 310, 106638 (2020)). By combing MOSFET and LC networks, a low-frequency detuning circuit design has been used effectively in a TORO coil configuration (de Vos, B. et al., Frontiers in Physics, 413 (2021)).

Dedicated Anatomy-specific Magnet Parallel Rx: Finally, a multichannel Rx-only array coil can be built for facilitating parallel imaging in the dedicated anatomy-specific magnet system. A coil geometry appropriate for a specific anatomy can be implemented here. It is contemplated that the shape of the coil can provide a convenient point for each coil element to be decoupled, either with capacitor network (Ianniello, et al., Magnetic Resonance in Medicine 82, 1566-1575 (2019)) or decoupling transformer (Nabeshima, T., Takahashi, T., Matsunaga, Y., Yamamoto, E. & Katakura, K. (Google Patents, 1996)). The subtasks of developing the proposed array coil can be list as below:

EM Simulation and Component Value Calculation. The array structure can be EM modelled using CST.

Bench development and decoupling improvements. The proposed array coil can be built on bench, and the decoupling network between each element can be developed and improved upon. Both ladder-network and transformer decoupling can be investigated. The winner of the two can be used on the final version of the array coil.

Detuning circuits. Detuning for this array is very similar to that of the array described above and thus the same circuit can be used.

### Improve Images Through Accumulated Data

With a fixed protocol on each MRI system, we can rapidly acquire a significant amount of data that can allow us to implement reconstructions that better incorporate scanner diagnostic data acquired through QA and system monitoring. We can develop machine learning and/or deep learning approaches to denoising and improving our image reconstructions. It is contemplated that these steps can result in improved SNR over the volume and faster reconstruction times with robustness to artifacts.

### Phase 3: Clinical Testing Phase

Phase 3 involves milestones that can be useful with respect to commencing clinical testing of our anatomy-specific MRI prototypes.

One aspect of Phase 3 involves clinical data collection. These identical clinical prototypes can be ready for collecting clinical data at the different sites. With systems installed in three sites (two clinical imaging centers, and the Yale MRRC) we can begin testing in three different patient groups. The first group includes patients with cancer diagnoses by needle biopsy but prior to any treatment. The second group includes patients who are scheduled to have a biopsy based on abnormal imaging. This group can include patients detected at screening as well as those with clinical signs of cancer (e.g., a palpable mass). Twenty to thirty percent of this group can have cancer diagnoses confirmed at biopsy, while the others can demonstrate benign lesions. The third group can include healthy volunteers who enroll for screening. This group can provide valuable information on throughput and ease of use of the devices in a healthy screening population. The cancer yield in this group can be less than 1%. For this process we can follow G×P guidelines as specified in ISO 13485 ((ISO), I. O. f. S. Medical devices—Quality management systems—Requirements for regulatory purposes [Internet]. Geneva, CH; (2016)).

Another aspect of Phase 3 involves assessment of clinical performance. Clinical performance in terms of detecting known cancers (patient group 1) can be assessed by measuring detectability of known lesions. Sensitivity and specificity can be assessed in an enriched population as defined by patients who have had an abnormal clinical exam and are scheduled for biopsy (patient group 2). Data on patient flow and image quality in a screening setting (patient group 3) can also be collected. It is desirable to aim for values of the order of 95% for cancer visibility.

Another aspect of Phase 3 is having a commercializable prototype with initial FDA engagement and clinical efficacy data that can be translated to a marketable device through transition to industry.

The final product from this work can be a prototype anatomy-specific MRI system that can have sufficient documentation and data to complete FDA approval and move to market. The system combines many developments in MRI disclosed herein in a unique package that allows for the design of a highly efficient anatomy-specific MRI device. This system can be low-cost, easy to site, and easy to operate. By making such systems available at 1/10th the cost of conventional MRI, we should be able to greatly increase access to MRI screening. MRI has been shown to be the best modality for detecting cancer in certain anatomies and the only reason it is not used routinely and access is very limited is because of the high cost of purchasing and operating a conventional MRI system. The disclosed MRI systems can solve this problem and this in turn can have a major impact on women's health and the war on cancer.

The technology we develop for this system is transferable to imaging other organs including, but not limited to, brain, breast, liver, spine, prostate, heart, or gynecologic parts. In some forms, the technology is transferable to other organs including, but not limited to, brain, liver, spine, prostate, heart, or gynecologic parts. In some forms, the technology is transferable to other organs and designed not involve breast anatomy. We envision for example a similar device for men for prostate imaging. This field-cycling non-uniform magnet approach can also be developed for cardiac and brain imaging applications. In these applications we envision building such devices into the patient beds in intensive care units such that the patients do not need to be disconnected from all of their tubing and moved into an MRI scanner to check on their status. In the intensive care setting each bed could have a local electromagnet and coils built in and these could all be connected to a central setup of power amplifiers, rf amplifier and a chiller. These are the most expensive components of this device and by multiplexing these to many front ends, tremendous cost savings could be had in siting these MRIs.

A final important application for our approach is the development of a system for assessing fatty liver disease. We are in a growing obesity epidemic in the USA and with that comes fatty liver disease which, if identified early can be effectively treated. It is contemplated that the disclosed MRI systems can be incorporated into an exam table that could be housed in a liver clinic such that assessments of fatty liver disease or cirrhosis could be made routinely on obese individuals and treatment started immediately if there are signs of liver damage. This could also have a major impact on health care in the USA.

Moreover, the development of low-cost and safe (no ionizing radiation) MRI could lead to imaging as a routine part of annual exams for all. With our approach, all exams can be conducted with identical protocols (technicians do not input any parameters into the scans), and therefore the images can be consistent in size/contrast/etc. The constancy of the anatomical images and the rapid accumulation of a large database of images over time can allow for the development of AI assisted radiology methods that can detect any changes (AI is more efficient at detecting change than making diagnosis). The use of AI in detecting changes can also lower the cost of exams by reducing the time radiologists need to spend with each case they read.

By having all exams conducted under the same protocols, and by having all images uploaded to the same database servers, evaluations can be done in real time by radiologists stationed in locations outside of the exam centers. This can be especially helpful for areas that lack radiologists, such as underserved or remote communities. In our business model we retain ownership of the MRI devices and hence the data and provide the radiology service. Such an arrangement maintains control of image quality and allows us to quickly build very valuable data for training AI-assisted radiology algorithms.

Future work could also extend these devices to accommodate biopsies due to the open nature of the disclosed anatomy-specific MRI systems. This new approach to MRI can also be expanded to other applications—where magnets are designed to fit specific anatomic locations. Similar open MRIs can be designed for head and heart imaging and be installed in patient beds in the neuro-intensive care unit and cardiac-intensive care unit as discussed earlier. By installing MRIs directly into the patient beds, patients can be imaged multiple times per day, without needing to move the patients. This could be especially helpful in rapidly progressing health problems where the continuous collection of images yields better health treatments. Such devices also could be built into a wall for weighted spine or other limb imaging.

A summary providing some more specific, non-limiting aspects of the disclosed MRI systems and methods are provided below:

### Phase 1: Hardware and Method Development

### A. Hardware Development

### 1. Gradients for NuB₀

1.1. Hardware can be built from 3 mm conductive copper with 35 (Gsi) and 28 (Glr) windings in a single layer for each channel. Following construction, gradients can be tested for resistance, inductance, and flow. They can then be matched and tuned to 25 A amplifiers (AE TECHRON) and tested at full current for heat, torquing, and coupling. 3D measurements of the static field for each channel can be acquired (resolving Bx, By and Bz), and we can also perform measurements at multiple locations to assess the field during a short impulse waveform. By acquiring these measurements at multiple locations, both the native waveform shape and cross-terms can be assessed to calculate the gradient input response function and design pre-emphasis.
1.2. Measurable standards for gradients include ramp time <200 us, average gradient strengths 25-40 mT/m over the targeted FOV, and heating below 37° C. for 60% duty cycle.

### 2. Tx/Rx Coil for NuB₀

2.1. The Tx/Rx solenoid can be built and connected to newly designed boards for Tx/Rx with MOSFETs at 1 MHz. The coils can be wound from 18 AWG copper wire and placed inside a slotted conductive shielded (Alon, et al., Magnetic Resonance in Medicine 80, 1233-1242 (2018)) (the shield is slotted to avoid induced eddy currents on the shield, while still preventing interference from other electronics). After bench measurements of matching and tuning, preliminary scans without a sample can be used to assess ringdown time. Q-damping circuits (Peshkovsky, et al., Journal of Magnetic Resonance 177, 67-73 (2005)) can be implemented if ring-down time is too long. B1+ can then be mapped across the field of view using our automated system.
2.2. Measurable standards for RF include S11>−15 dB, with ring down time less than 50 μs and B1+ homogeneity within 5% of relative standard deviation (SD).

### 3. Polarizing Magnet for Dedicated Anatomy-Specific Magnetic

3.1. The polarizing magnet can be built from 4.5 mm hollow conductive copper wire with 25-windings per layer and 9 layers. After initial measurements of resistance, inductance and water flow, the system can be matched and tuned to the amplifier (275A Performance Systems, Inc) and tested to full current for assessment of heating and torque. Spatial mapping of the magnetic field can be acquired to assess both magnitude and direction of field at all locations. As with spatial encoding gradients, these can be used to design pre-emphasis for higher fidelity outputs.
3.2. Measurable standards for DBM polarizing magnet include field magnitude between 0.4 and 1.0 T over targeted FOV, ramp times <30 ms, and magnet temperature below 37° C. for 100% duty cycle.

### 4. Gradients for Dedicated Anatomy-Specific Magnetic

4.1. Coil manufacture and testing can follow procedures outlined for NuBo gradients; only the winding pattern is significantly different.
4.2. Measurable standards: Also same, i.e., ramp time <200 μs and average gradient strengths >40 mT/m over the targeted FOV, heating below 37° C. for 60% duty cycle (our imaging sequences are nowhere near a 60% duty cycle because our sequences require time in the low field imaging phase, and this breaks up the high-field polarization phase).
   5. Tx/Rx Coil for dedicated anatomy-specific magnetic
5.1. Coil manufacture and testing can follow procedure outlined for NuBo solenoid, as only the winding pattern is significantly different.
5.2. Measurable standards: Also same, i.e., S11 better than −15 dB, with ring down time less than 50 μs and B1+ homogeneity within 5% of the standard deviation.

### B. System Developments Applicable to Both NuBo and Dedicated Anatomy-Specific Magnet

### 1. T1w/T2w Sequence Development

1.1. The existing TSE sequence can be the first method tested with each new hardware setup. This can be used to measure SNR across echo trains and slices, both with and without spatial encoding. Gradient refocused spin-warp encoding trajectory can be used for spatial encoding following a polarization period of 6 seconds (polarization accumulates at a rate of T1). Encoding can be set up such that acquisition of central k-space can be either ˜200 ms for a T2w sequence, or ˜10 ms for a T1w sequence. Following initial phantom imaging studies to establish image quality metrics, multi-slice images can be acquired in X healthy volunteers.
1.2. Measurable standards: Resolution in phantoms and in vivo can be better than 1 mm in plane, with slice thickness <3 mm. Temporal resolution for a volume can be <30 seconds.

### 2. Contrast-Enhanced Sequence Development

2.1. Phantom studies using the T1 contrast phantom (water doped with different concentrations of gadobenate dimeglumine) can be improved to achieve the target resolution with less than 2-minute scan time. Imaging contrast in phantoms can also be quantified on both scanners. Following this improvement, the scans can be run on healthy subjects and reviewed by radiologists to confirm in vivo image quality.
2.2. Measurable standards: T1w images can be acquired with 1 mm in plane resolution in under 2 minutes.

### 3. Fat or Water Suppressed Sequence Development

3.1. Fat or water suppression can be achieved using the T1w TSE sequence, manipulating pre-polarization timing or polarity to suppress fat or water. Initial studies can be performed in phantoms of oil and water. The developed sequence can then be tested in healthy volunteers. In vivo images can be assessed by radiologists for image quality.
3.2. Measurable standards: Contrast-to-Noise (CNR)>5 between fat and water in phantom studies and humans.

### 4. DWI Sequence Development

4.1. Diffusion weighted imaging can be accomplished by incorporating ramp up of the polarizing magnet between RF pulses in the first echo times of the train. We can ramp to a through-slice gradient amplitude of >200 mT/m for all slices which can provide high b-value in short echo times. Earlier echo spacings may need to be slightly longer (˜5 ms) to achieve high b-value, but echoes used for spatial encoding can have 2 ms spacing. After initial testing in phantoms to establish image quality metrics, healthy volunteers can be imaged and assessed by radiologists for image quality.
4.2. Measurable standards: In plane resolution can be better than 3 mm in plane with 5 mm slice selection 115. As in high field imaging, diffusion weighted images are expected to need somewhat lower spatial resolution due to the SNR loss needed to achieve diffusion contrast.

### 5. Image Reconstruction

5.1. The effect of concomitant fields can be estimated from initial measurements of the magnetic field in polarizing and gradient hardware. These can be incorporated into encoding matrix to properly model phase evolution during spatial encoding. Initial reconstruction algorithms can use GPU-accelerated algebraic reconstruction to provide maximum flexibility so that all hardware characterization can be accurately incorporated into encoding matrix. Future developments can improve reconstruction time and implement denoising and regularization via machine learning.
5.2. Measurable standards: Reconstruction times <2 minutes per volume with SNR improvements >3 dB.

### 6. Standalone Console

6.1. Controller and component boards can be designed to minimize cost and complexity using existing open-source solutions for Tx, Rx, and waveform generator logic. The controller sequencer can be built to both update peripheral boards and cue them to execute. The final implementation can include a sparse user interface that can be unlocked by field engineers to access additional parameters and information.
6.2. Measurable standards: Standalone console coordinates all sequence elements with proper execution.

### 7. Compare Prototypes and Choose Best Scanner

7.1. Data from human and phantom studies can be analyzed for resolution and SNR. Beyond this, we can consider results from contrast studies and image quality ratings.
7.2. Measurable standards: The chosen scanner can meet all predefined metrics for image quality. Beyond this, the system with best SNR, stability.

### Phase 2: Finalize Design and Install Clinical Scanners

### C. Implement Finalized Hardware Design

### 1. Build First Clinical Scanner

1.1. The first clinical scanner can be modified to optimize ergonomics. If dedicated anatomy specific magnet is found to be the superior scanner, this is expected to be the only deviation from the prototype. If NuB0 is found to be the best scanner, we can build an improved anatomy-specific version, NuB02.0, which provides better polarization. All manufacturing details of this scanner can be carefully documented and controlled in preparation for FDA filing. QA acceptance can follow the validation protocols outlined for the Phase 1 development scanner.
1.2. Measurable standards: First clinical scanner preferably passes all criteria for performance and safety as outlined previously for development prototype.

### 2. Test First Clinical Scanner

2.1. Final testing of the first clinical scanner, installed at a patient-only room of MRRC, can proceed by imaging 8 subjects in both the prototype and first clinical system. In the unlikely event that image quality is lower than that observed in the prototype, an exact replica of the winning prototype (either DBM or original NuB0 for prone imaging) can be built for installation in clinical sites.
2.2. Measurable standards: First clinical scanner matches performance of development prototype.

### 3. Subsequent Clinical Installations and Commencement of FDA Process

3.1. Careful documentation of all manufacturing, both for first and subsequent clinical scanners, can be gathered for commencement of FDA process. All components can be individually and jointly tested using the criteria for performance and safety outlined for the development prototype. Following finalization of simplified console interface, techs can be trained to run QA as well as contrast-enhanced human studies.
3.2. Measurable standards: Installation of final clinical scanners and commencement of FDA approval process for 510 k filing.

### D. System Monitoring for Safety and QA

### 1. Safety Monitoring

1.1. Permanently connected magnetometers can be installed at the edge of each magnet. These, in combination with previously acquired 3D maps, can be used to monitor field stability across time and also to prevent scans that may produce PNS. Notably, the maximum slew rate of our systems (˜0.5 T in 35 ms) is still well below the cardiac stimulation limit 116, which itself is set conservatively by about an order of magnitude. B1 can be similarly monitored using a sniffer coil placed outside the FOV and, in combination with previous measurements, can be used to monitor SAR in real-time. These, as well as temperature monitors for all electromagnets can be interfaced to console which can monitor this input to prevent scans that violate safety limits.
1.2. Measurable standards: Scanner automatically detects and prevents scans that violate prescribed dB/dt, SAR, or temperature limits.

### 2. Quality Assurance

2.1. A daily scan protocol can be established to confirm proper system function at the start of each day's operation. These scans can be run on a standard resolution phantom with standard positioning, so that expected data can be easily analyzed. Analyses can confirm that all hardware is within spec including polarizing field strength, gradient shape, RF power, and receiver SNR. EMI functionality can be confirmed via a scan that excludes signal excitation. The console can run this series consecutively and also analyze the data, so no user interaction is required. If service is needed, the system automatically sends results for troubleshooting.
2.2. Measurable standards: scanner performs scan series and analyzes data in an automated manner. Aside from positioning the standardized phantom and beginning the procedure, no further interaction should be required.

### 3. Advanced System Characterization

3.1. Data collected for safety monitoring, along with environmental variables, can be accumulated in tandem with QA scans. This data can be assembled and could be mined to identify patterns between QA image metrics and hardware variables.
3.2. Measurable standards: Contemporaneous data, both image data and monitored variables, from all sites is available and searchable.

### E. Further Improvements to SNR and Speed

### 1. Develop Multichannel Receive for Accelerating Image Acquisitions

1.1. Build separate Tx coil and a multichannel receive coil for winning scanner (winding depends on orientation of polarization fields). Preliminary data has shown the feasibility of decoupling array elements at low field, and this can be refined with either a ladder network or transformer decoupling. Detuning circuits can be built to protect receive chain from Tx power. Scans acquired with multichannel receive can be tested for their ability to shorten scan time via parallel imaging.
1.2. Measurable standards: Acceleration factors of 2 with negligible ghosting artifact can be achieved.

### 2. Improve Images Through Accumulated Data

2.1. Implement reconstructions that better incorporate scanner diagnostic data acquired through QA and system monitoring.
2.2. Measurable standards: Improved SNR or faster reconstruction.

### Phase 3: Clinical Testing

### F. Quantify Conspicuity of Known Lesions

1. Acquire Data from Patients with Known Lesions (Biopsy-Confirmed)
1.1. Recruit N=120 patients who have had previous MRI-detectable disease which was later biopsy-confirmed as malignant.
1.2. Measurable standards: 120 patients recruited and imaged within 2 years across 3 sites with mean detectability target score of >4 but acceptable score >3.

### 2. Quantify Detectability

2.1. A team of radiologists can rate detectability of any visible lesions on a 5-point scale. In some cases more than one lesion may be perceived, all lesions can be given score but the most detectable lesion can serve for the primary rating on the 5-point scale. This data can also help train radiologists on the proper interpretation of our images.
2.2. Measurable standards: Average detectability score can be 4 or higher on confirmed lesions.

### G. Quantify Detectability and Suspicion in Lesion-Enriched Population

### 1. Acquire Data in Patients are Going for Biopsy (not Confirmed Cancer).

1.1. 595 patients who had a suspicious finding on previous scan but have not yet received a biopsy can be recruited. Biopsy results from these patients can also be collected.
1.2. Measurable standards: 595 patients will be recruited and imaged within 2 years across 3 sites. We anticipate 20-30% of these patients test positive for cancer. Therefore, this is a screening study with an enriched population.

### H. Test Through-Put and Workflow in a Screening Setting (Healthy Subjects)

### 1. Acquire Screening MRIs on 120 Subjects Recruited From the General Population.

1.1. Subjects can undergo our regular MRI protocol and complete a survey on the procedure as well including the study mechanisms (ease of entry/exist, duration, comfort).

### 2. Rate the Image Quality.

2.1. Our radiology team can read all the cases (and flag any that require follow up) as well as rate image quality in terms of contrast, snr, consistency of image quality from case-to-case, and any artifacts (motion).
2.2. Measurable standards: Good quality is consistently achieved and the subject feedback is positive.

The disclosed subject matter can be further illustrated by the following numbered paragraphs:
1. A magnetic resonance imaging (MRI) system, preferably compact MRI system, suitable for imaging in mixed-use rooms, the MRI system containing:
a first component comprising an open, field-cycling magnet configured to produce a first non-uniform B₀ magnetic field and a second non-uniform B₀ magnetic field having a field strength different from that of the first non-uniform B₀ magnetic field, and
one or a plurality of second components operably linked to the first component and configured to produce one or a plurality of nonlinear spatial encoding gradients.
2. The MRI system of paragraph 1, wherein the open, field-cycling magnet; the spatial encoding gradients; or a combination thereof, are customizable and/or customized to a specific imaging application.
3. The MRI system of paragraph 1 or 2, wherein the open, field-cycling magnet and the spatial encoding gradients are customizable and/or customized to a specific imaging application.
4. The MRI system of any one of paragraphs 1 to 3, wherein the first non-uniform B₀ magnetic field has a field strength greater than that of the second non-uniform B₀ magnetic field.
5. The MRI system of any one of paragraphs 1 to 4, wherein the first non-uniform B₀ magnetic field is configured to generate a slice-selective gradient.
6. The MRI system of any one of paragraphs 1 to 5, wherein the magnet is an electromagnet, such as a resistive electromagnet or a superconducting electromagnet.
7. The MRI system of any one of paragraphs 1 to 6, wherein the one or the plurality of second components contain: (i) one or more radiofrequency coils and/or parallel receiver coils; (ii) one or more nonlinear gradient coils; or (iii) both (i) and (ii); capable of being configured to produce the one or the plurality of nonlinear spatial encoding gradients.
8. The MRI system of any one of paragraphs 1 to 7, wherein the one or plurality of second components contain: (i) one or more radiofrequency coils and/or receiver coils (e.g., parallel receiver coils); (ii) one or more nonlinear DC gradient coils; or (iii) both (i) and (ii); capable of being tailored specifically to the first non-uniform B₀ magnetic field, the second non-uniform B₀ magnetic field, or both.
9. The MRI system of any one of paragraphs 1 to 8, wherein the one or plurality of second components contain: (i) one or more radiofrequency coils and/or receiver coils (e.g., parallel receiver coils); (ii) one or more nonlinear DC gradient coils; or (iii) both (i) and (ii); capable of being configured to reconstruct an image of a sample/volume of interest.
10. The MRI system of any one of claims 1 to 8, wherein the one or plurality of second components contain one or more radiofrequency coils and/or parallel receiver coils.
11. The MRI system of any one of paragraphs 1 to 10, wherein the one or plurality of second components contain one or more radiofrequency coils and/or receiver coils (e.g., parallel receiver coils), wherein the one or more radiofrequency coils have a non-planar configuration, a non-horizontal configuration, or both.
12. The MRI system of any one of paragraphs 1 to 9, wherein the plurality of nonlinear spatial encoding gradients spans a three-dimensional volume space, are sequentially generated in an imaging region, and/or separately generated in an imaging region.
13. The MRI system of any one of paragraphs 1 to 12, wherein:
the first non-uniform B₀ magnetic field polarizes spins in a sample/volume of interest, and/or
the second non-uniform B₀ magnetic field is applied in an imaging phase for the sample/volume of interest.
14. The MRI system of any one of claims 1 to 13, operably linked to a computing device that controls the operation of the open, field-cycling magnet; the one or the plurality of second components; the one or more radiofrequency coils; the one or more receiver coils (e.g., parallel receiver coils); the one or more nonlinear DC gradient coils; or a combination thereof, preferably wherein the computing device comprises tablet computers, servers, desktop computers, laptop computers, mainframes, or a combination thereof.
15. A method of imaging a sample/volume of interest using the MRI system of any one of paragraphs 1 to 14, the method involving:
field cycling between the first non-uniform B₀ magnetic field and the second non-uniform B₀ magnetic field.
16. The method of paragraph 15, wherein the first non-uniform B₀ magnetic field is applied to the sample/volume of interest prior to applying the second non-uniform B₀ magnetic field to the sample/volume of interest.
17. The method of paragraph 15 or 16, wherein field cycling between the first non-uniform B₀ magnetic field and the second non-uniform B₀ magnetic field is achieved by controlling/altering a current supplied to the magnet.
18. The method of any one of paragraphs 15 to 17, wherein MRI images are reconstructed from (parallel or single-channel) received magnetic resonance signals from RF coils using algebraic reconstruction.
19. The method of paragraph 19, wherein image reconstruction does not use standard Fourier-based image reconstruction.
20. The method of any one of paragraphs 15 to 19, wherein the sample/volume of interest is not a breast anatomy.

It will be appreciated that variations in intensities and alternatives in elements of the components shown will be apparent to those skilled in the art and are within the scope of disclosed forms. All parts or amounts, unless otherwise specified, are by weight. Use of the term “about” is intended to describe values either above or below the stated value in a range of approx. +/−10%. Examples of values within this range are +/−1%, +/−2%, +/−3%, +/−4%, +/−5%, +/−6%, +/−7%, +/−8%, +/−9%, and +/−10%.

Those skilled in the art will recognize, or be able to ascertain using no more than routine experimentation, many equivalents to the specific embodiments of the invention described herein. Such equivalents are intended to be encompassed by the following claims.

We claim:

1. A magnetic resonance imaging (MRI) system, preferably compact MRI system, suitable for imaging in mixed-use rooms, the MRI system comprising:
a first component comprising an open, field-cycling magnet configured to produce a first non-uniform B₀ magnetic field and a second non-uniform B₀ magnetic field having a field strength different from that of the first non-uniform B₀ magnetic field, and
one or a plurality of second components operably linked to the first component and configured to produce one or a plurality of nonlinear spatial encoding gradients.

2. The MRI system of claim 1, wherein the open, field-cycling magnet; the spatial encoding gradients; or a combination thereof, are customizable and/or customized to a specific imaging application.

3. The MRI system of claim 1, wherein the open, field-cycling magnet and the spatial encoding gradients are customizable and/or customized to a specific imaging application.

4. The MRI system of claim 1, wherein the first non-uniform B₀ magnetic field has a field strength greater than that of the second non-uniform B₀ magnetic field.

5. The MRI system of claim 1, wherein the first non-uniform B₀ magnetic field is configured to generate a slice-selective gradient.

6. The MRI system of claim 1, wherein the magnet is an electromagnet, such as a resistive electromagnet or a superconducting electromagnet.

7. The MRI system of claim 1, wherein the one or the plurality of second components comprise: (i) one or more radiofrequency coils and/or parallel receiver coils; (ii) one or more nonlinear gradient coils; or (iii) both (i) and (ii); capable of being configured to produce the one or the plurality of nonlinear spatial encoding gradients.

8. The MRI system of claim 1, wherein the one or plurality of second components comprise: (i) one or more radiofrequency coils and/or receiver coils; (ii) one or more nonlinear DC gradient coils; or (iii) both (i) and (ii); capable of being tailored specifically to the first non-uniform B₀ magnetic field, the second non-uniform B₀ magnetic field, or both.

9. The MRI system of claim 1, wherein the one or plurality of second components comprise: (i) one or more radiofrequency coils and/or receiver coils; (ii) one or more nonlinear DC gradient coils; or (iii) both (i) and (ii); capable of being configured to reconstruct an image of a sample/volume of interest.

10. The MRI system of claim 1, wherein the one or plurality of second components comprise one or more radiofrequency coils and/or parallel receiver coils.

11. The MRI system of claim 1, wherein the one or plurality of second components comprise one or more radiofrequency coils and/or receiver coils, wherein the one or more radiofrequency coils have a non-planar configuration, a non-horizontal configuration, or both.

12. The MRI system of claim 1, wherein the plurality of nonlinear spatial encoding gradients spans a three-dimensional volume space, are sequentially generated in an imaging region, and/or separately generated in an imaging region.

13. The MRI system of claim 1, wherein:
the first non-uniform B₀ magnetic field polarizes spins in a sample/volume of interest, and/or
the second non-uniform B₀ magnetic field is applied in an imaging phase for the sample/volume of interest.

14. The MRI system of claim 1, operably linked to a computing device that controls the operation of the open, field-cycling magnet; the one or the plurality of second components; the one or more radiofrequency coils; the one or more receiver coils; the one or more nonlinear DC gradient coils; or a combination thereof.

15. A method of imaging a sample/volume of interest using the MRI system of claim 1, the method comprising:
field cycling between the first non-uniform B₀ magnetic field and the second non-uniform B₀ magnetic field.

16. The method of claim 15, wherein the first non-uniform B₀ magnetic field is applied to the sample/volume of interest prior to applying the second non-uniform B₀ magnetic field to the sample/volume of interest.

17. The method of claim 15, wherein field cycling between the first non-uniform B₀ magnetic field and the second non-uniform B₀ magnetic field is achieved by controlling/altering a current supplied to the magnet.

18. The method of claim 15, wherein MRI images are reconstructed from received magnetic resonance signals from RF coils using algebraic reconstruction.

19. The method of claim 19, wherein image reconstruction does not use standard Fourier-based image reconstruction.

20. The method of claim 15, wherein the sample/volume of interest is not a breast anatomy.
